(19) United States
(12) Patent Application Publication
(10) Pub. No.: US 2026/0074570 A1
(43) Pub. Date: Mar. 12, 2026

(54) METHOD AND APPARATUS FOR TRANSMITTING WIRELESS POWER FOR ELECTRIC VEHICLE WITH ELECTROMAGNETIC WAVE SHIELDING FUNCTION

(71) Applicant: ELECTRONICS AND TELECOMMUNICATIONS RESEARCH INSTITUTE, Daejeon (KR)

(72) Inventors: Seong Min KIM, Daejeon (KR); Gwang Zeen KO, Daejeon (KR); Kye Seok YOON, Sejong-si (KR); In Kui CHO, Daejeon (KR)

(73) Assignee: ELECTRONICS AND TELECOMMUNICATIONS RESEARCH INSTITUTE, Daejeon (KR)

(21) Appl. No.: 19/191,160

(22) Filed: Apr. 28, 2025

(30) Foreign Application Priority Data
Sep. 6, 2024 (KR) 10-2024-0121526

(51) Int. Cl. H02J 50/70; B60L 53/12; B60L 53/30; B60L 53/60; H02J 50/00; H02J 50/10; H05K 9/00

(52) U.S. Cl. CPC H02J 50/70; B60L 53/12; B60L 53/30; B60L 53/60; H02J 50/005; H05K 9/0088; H02J 50/10

(57) ABSTRACT

The present disclosure relates to a method of electric vehicle wireless power transmission and a device therefor with an electromagnetic wave shielding function. According to an aspect of the present disclosure, provided is a wireless power transmission device for wirelessly charging an electric vehicle, including: a transmitting coil configured to generate a magnetic field for wireless charging; at least one shielding panel positioned around the transmitting coil; at least one rotary shaft each attached to an edge of the at least one shielding panel and formed to be able to each adjust a standing angle of the at least one shielding panel by rotation; and a controlling unit configured to drive the at least one rotary shaft to adjust the standing angle of the at least one shielding panel if wireless charging of an electric vehicle is started.

### CROSS-REFERENCE TO RELATED APPLICATION

The present application claims priority to Patent Application No. 10-2024-0121526, filed on in Korea Intellectual Property Office on Sep. 6, 2024, the entire contents of which are incorporated herein by reference.

### TECHNICAL FIELD

The present disclosure relates to a method of electric vehicle wireless power transmission and a device therefor with an electromagnetic wave shielding function.

### BACKGROUND

The content described below merely provides background information related to an embodiment of the present disclosure, and does not constitute the prior art.

FIG. 1 is a diagram illustrating a general electric vehicle wireless charging scheme.

As shown in FIG. 1, a transmission pad 110 included in a general electric vehicle wireless power transmission device is horizontally disposed on a surface of or inside a parking lot or road, and a magnetic field is transferred from the transmission pad 110 to a reception pad 120 horizontally mounted on a bottom surface of an electric vehicle 101 to wirelessly charge the reception pad 120.

As described above, it is common for surfaces of the transmission pad 110 and the reception pad 120 to be exposed to the air to transfer power to the reception pad 120 from the transmission pad 110 mounted on a surface of or inside a parking lot or road.

When a magnetic field is generated and transferred through a structure exposed to the air as described above, electronic devices and the human body around wireless power transmission devices are affected by electromagnetic waves generated and radiated by the generated magnetic field, and thus, the surrounding electronic devices may malfunction, and heat generation may be induced in the human body due to stimulation or thermal effect.

Various methods for reducing such electromagnetic wave influences on wireless power transmission devices have been attempted, but a method using a separate shielding coil for shielding electromagnetic waves in a specific direction or reducing the influence of electromagnetic waves has been proposed in the prior art.

FIG. 2 is a diagram illustrating a conventional transmitting coil and electromagnetic wave shielding structure for reducing electromagnetic waves.

The electromagnetic wave shielding structure shown in FIG. 2 has a structure in which a power convey assembly 24 including a ferrite 22 stacked on a lower portion of a transmitting coil 21, and a shielding structure 25 forming an accommodation space of the power convey assembly 24 and positioned on a bottom surface and a side surface of the power convey assembly 24 are formed, and which is open to an upper surface of the power convey assembly 24, in order to reduce electromagnetic wave influences.

The electromagnetic wave shielding structure of FIG. 2 may reduce electromagnetic wave influences in a ground direction but it is difficult to substantially reduce electromagnetic waves for a side surface of the open transmitting coil 21.

In addition, in another prior art proposed to reduce electromagnetic wave influences on electric vehicle wireless power transmission devices, a method for reducing electromagnetic waves using a loop-shaped electromagnetic wave shielding device is proposed. However, the proposed method is a method for shielding electromagnetic waves using a separate loop coil, and has a limitation in that only a specific frequency component may be reduced, and thus it is difficult to reduce electromagnetic waves of all harmonic components generated in wireless power transmission devices.

### SUMMARY

A main objective of the present disclosure is to provide a method and apparatus for transmitting wireless power for electric vehicle with an electromagnetic wave shielding function.

Technical problems of the present disclosure are not limited to the above-mentioned problems, and other problems that are not mentioned will be clearly understood by those skilled in the art from the following description.

According to an aspect of the present disclosure, provided is a wireless power transmission device for wirelessly charging an electric vehicle, including: a transmitting coil configured to generate a magnetic field for wireless charging; at least one shielding panel positioned around the transmitting coil; at least one rotary shaft each attached to an edge of the at least one shielding panel and formed to be able to each adjust a standing angle of the at least one shielding panel by rotation; and a controlling unit configured to drive the at least one rotary shaft to adjust the standing angle of the at least one shielding panel if wireless charging of an electric vehicle is started.

According to another aspect of the present disclosure, provided is a method of wireless power transmission for wirelessly charging an electric vehicle by the wireless power transmission device including a transmitting coil configured to generate a magnetic field for wireless charging, at least one shielding panel positioned around the transmitting coil, and at least one rotary shaft each attached to an edge of the at least one shielding panel and formed to be able to each adjust a standing angle of the at least one shielding panel by rotation, the method including: a wireless charging confirmation process of confirming whether wireless charging of an electric vehicle is started; a standing angle adjustment process of driving at least one rotary shaft according to the start of the wireless charging to adjust a standing angle of the at least one shielding panel; and a power generation process of generating power of the transmitting coil after the adjustment of the standing angle.

As described above, according to an embodiment of the present disclosure, a shielding panel is configured in a wireless power transmission device and is erected during a wireless charging process by the wireless power transmission device, and therefore, an electromagnetic wave shielding effect may be enhanced.

In addition, the present disclosure may be applied to various vehicle charging environments by measuring a height between the wireless power transmission device and a bottom surface of a vehicle using a distance sensor, and calculating a standing angle of the shielding panel according to the measured height.

In addition, the proposed shielding panel may be used to achieve an effect of shielding both a magnetic field and an electric field.

The effects of the present disclosure are not limited to the above-mentioned effects, and other effects that are not mentioned will be clearly understood by those skilled in the art from the following description.

### BRIEF DESCRIPTION OF THE DRAWINGS

FIG. 1 is a diagram illustrating a general electric vehicle wireless charging scheme.

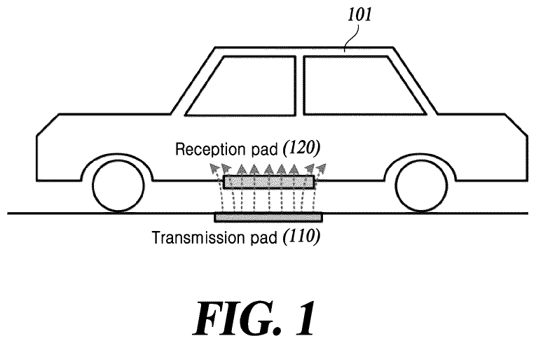

FIG. 2 is a diagram illustrating a conventional transmitting coil and electromagnetic wave shielding structure for reducing electromagnetic waves.

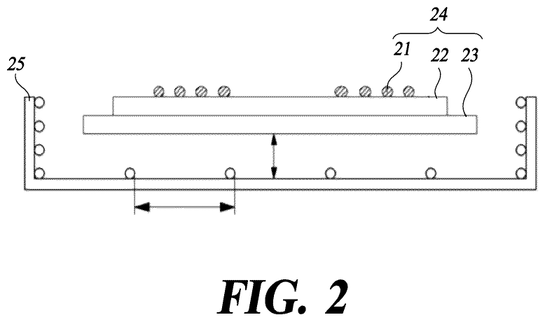

FIG. 3 is a diagram illustrating a configuration of a wireless power transmission device according to an embodiment of the present disclosure.

FIG. 4 is a diagram illustrating a cross-section taken along A-A′ in FIG. 3 as viewed in a Z direction.

FIG. 5 is a diagram exemplarily illustrating a shape of a cross-section taken along B-B′ in FIG. 3 as viewed in a Z direction and an electric vehicle together, as a case where the electric vehicle moves over a fixed wireless power transmission device 300 for wireless charging.

FIG. 6 is a diagram exemplarily illustrating a shape when each shielding panel is erected at a certain standing angle.

FIG. 7 is a diagram illustrating a shape of the wireless power transmission device 300 after a moving process and a standing angle calculation process of a vehicle are completed and wireless charging is started.

FIG. 8 is a flowchart illustrating the method of wireless power transmission according to an embodiment of the present disclosure.

### DETAILED DESCRIPTION

Hereinafter, some embodiments of the present disclosure will be described in detail with reference to exemplary drawings. Note that, in adding reference numerals to components in each drawing, the same components are denoted by the same reference numerals as much as possible even if they are shown in different drawings. In addition, in describing the present disclosure, when it is determined that a specific description of a related known configuration or function may obscure the gist of the present disclosure, a detailed description thereof will be omitted.

In describing components of embodiments of the present disclosure, expressions such as first, second, i), ii), a), and b) may be used. These expressions are only used to distinguish components from other components, and the nature, sequence, order, or the like of the corresponding components is not limited by the expressions. In the specification, when a part “includes” or “comprises” a component, unless there is an explicit description to the contrary, the part may further include other components rather than excluding the other components.

The detailed description set forth below in connection with the appended drawings is intended to describe exemplary embodiments of the present disclosure and is not intended to represent the only embodiments in which the present disclosure may be practiced.

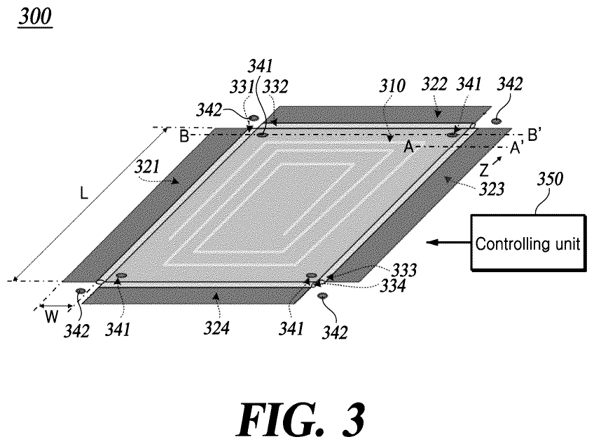

FIG. 3 is a diagram illustrating a configuration of a wireless power transmission device according to an embodiment of the present disclosure.

As shown in FIG. 3, a wireless power transmission device 300 according to an embodiment of the present disclosure is a device for wirelessly charging an electric vehicle 101, and may be implemented by including a transmitting coil 310, shielding panels 321, 322, 323, and 324, rotary shafts 331, 332, 333, and 334, distance sensors 341 and 342, and a controlling unit 350. The wireless power transmission device 300 according to an embodiment of the present disclosure may be implemented by omitting some components in FIG. 3 or by adding other components that are not shown in FIG. 3.

The transmitting coil 310 generates a magnetic field for wireless charging of the electric vehicle 101 when power is applied.

The shielding panels 321, 322, 323, and 324 are formed to be positioned around the transmitting coil 310 to shield a magnetic field generated in the transmitting coil 310.

The entirety of the shielding panels 321, 322, 323, and 324 surrounds the transmitting coil 310 from all sides, and each has a certain length L and a certain width W. Specifically, as illustrated in FIG. 3, the shielding panels 321, 322, 323, and 324 are respectively formed on four surfaces in front-rear and left-right directions with respect to the transmitting coil 310.

Each of the rotary shafts 331, 332, 333, and 334 is implemented in a form of being attached to one edge of corresponding one of the shielding panels 321, 322, 323, and 324 in a longitudinal direction. In other words, a first rotary shaft 331 is attached to an edge of a first shielding panel 321 in a longitudinal direction, a second rotary shaft 332 is attached to an edge of a second shielding panel 322 in a longitudinal direction, a third rotary shaft 333 is attached to an edge of a third shielding panel 323 in a longitudinal direction, and a fourth rotary shaft 334 is attached to an edge of a fourth shielding panel 324 in a longitudinal direction.

When positions where the rotary shafts 331, 332, 333, and 334 are formed are connected to each other, a rectangular shape that surrounds the transmitting coil 310 from all sides is formed.

Each of the rotary shafts 331, 332, 333, and 334 is formed to be rotatable around the center thereof. Each of the rotary shafts 331, 332, 333, and 334 is formed to be able to each adjust standing angles of the shielding panels 321, 322, 323, and 324 by rotation around the center thereof.

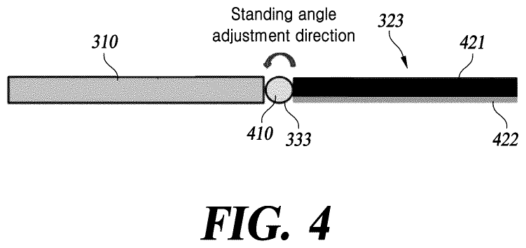

FIG. 4 is a diagram illustrating a cross section taken along A-A′ in FIG. 3 as viewed in a Z direction.

As shown in FIG. 4, a fourth rotary shaft 334 is formed to be rotatable around the center thereof 410. The fourth rotary shaft 334 is formed to be able to adjust a standing angle of a fourth shielding panel 324 by rotation around the center 410 thereof.

As described above, each of the rotary shafts 331, 332, 333, and 334 is formed to be rotated around the center thereof to be able to each adjust standing angles of the corresponding shielding panels 321, 322, 323, and 324 in an upward direction.

In addition, as shown in FIG. 4, in a configuration of each of the shielding panels 321, 322, 323, and 324 in a non-standing state (i.e., a state in which a standing angle is 0°), an upper portion thereof is formed of a magnetic body 421 such as a ferrite core, and a lower portion thereof is formed of a metal plate 422 capable of shielding an electric field. In other words, the magnetic body 421 is disposed to face a lower surface of an electric vehicle 101, and the metal plate 422 is disposed to face a lower surface (i.e., the ground) of the magnetic body 421.

As described above, a magnetic field and an electric field may be blocked by arrangement of the magnetic body 421 and the metal plate 422.

The distance sensors 341 and 342 measure a distance between the wireless power transmission device 300 and a bottom surface of the electric vehicle 101. The distance sensors 341 and 342 include four inner distance sensors 341 installed inside a rectangular shape and four outer distance sensors 342 installed outside the rectangular shape with respect to the rectangular shape formed by the rotary shafts 331, 332, 333, and 334.

The four inner distance sensors 341 are respectively disposed around four inner vertices of the rectangular shape.

The four outer distance sensors 342 are respectively installed around four outer vertices of the rectangular shape. The four outer distance sensors 342 are respectively disposed adjacent to left and right side-surfaces of the shielding panels 321, 322, 323, and 324 in a longitudinal direction before standing, and are disposed at positions that do not overlap positions of the shielding panel 321, 322, 323, and 324 before standing.

The controlling unit 350 calculates a height from the wireless power transmission device 300 to the bottom surface of the electric vehicle 101 according to a distance measured by each of the distance sensors 341 and 342 and adjusts a standing angle for rotating each of the rotary shafts 331, 332, 333, and 334 according to a calculated height.

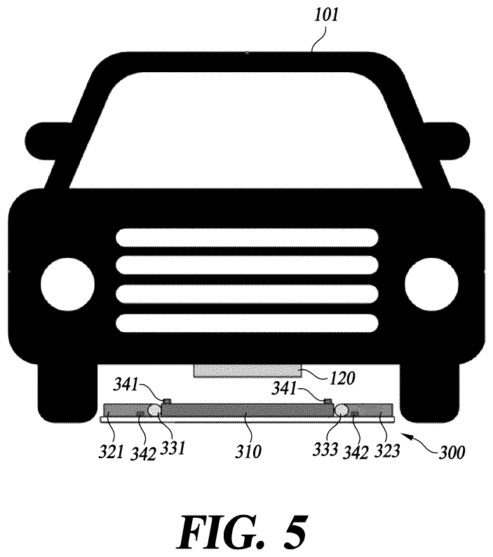

FIG. 5 is a diagram illustrating a shape of a cross-section taken along line B-B′ in FIG. 3 as viewed in a Z direction and the electric vehicle together, as a case where the electric vehicle moves for wireless charging over the fixed wireless power transmission device 300.

As shown in FIG. 5, an operation when the electric vehicle 101 moves while the transmitting coil 310 is fixed to the ground is performed as follows.

When the electric vehicle 101 moves over the wireless power transmission device 300, the controlling unit 350 continuously calculates a distance from the wireless power transmission device 300 to the bottom surface of the electric vehicle 101 by using the distance sensors 341 and 342 until the electric vehicle 101 reaches an optimal position.

The controlling unit 350 compares all measured distance values until the electric vehicle 101 reaches the optimal position and stops to calculate the minimum distance from the wireless power transmission device 300 to the bottom surface of the electric vehicle 101.

The controlling unit 350 calculates standing angles of the shielding panels 321, 322, 323, and 324 using the calculated minimum distance.

When the electric vehicle 101 reaches the optimal position and wireless charging is started, the controlling unit 350 operates to drive each of the rotary shafts 331, 332, 333, and 334 to stand each of the shielding panels 321, 322, 323, and 324 by a calculated standing angle, such that all four outer surfaces of the transmitting coil 310 are shielded.

The controlling unit 350 calculates the standing angles of the shielding panels 321, 322, 323, and 324 by Mathematical Formula 1 using the width (W) of the shielding panels 321, 322, 323, and 324 and the calculated minimum distance from the wireless power transmission device 300 to the bottom surface of the electric vehicle 101.

$$Standing angle = {\{ sin \}}^{⋀} \{ - 1 \} ( \{ measured minimum distance - distance margin \} over \{ width of shielding panel \} ) \qquad Mathematical Formula 1$$

In the Mathematical Formula 1, the distance margin refers to a preset margin for preventing at least any one of the shielding panels 321, 322, 323, and 324 and a lower surface of the electric vehicle 101 from colliding with each other. The distance margin is determined by a user in consideration of a thicknesses of the shielding panels 321, 322, 323, and 324, measurement errors of the distance sensors 341 and 342, and the like.

A width of each of the shielding panels refer to a width W of each of the shielding panels 321, 322, 323, and 324, and is equal to the maximum height of an edge of each of the shielding panels 321, 322, 323, and 324 when the shielding panels 321, 322, 323, and 324 are erected at 90°.

Even when the electric vehicle 101 is stopped and the wireless power transmission device 300 moves toward the bottom surface of the electric vehicle 101 to perform wireless charging, the controlling unit 350 continuously measures a distance from the wireless power transmission device 300 to the bottom surface of the electric vehicle 101 in all sections in which the wireless power transmission unit 300 moves, and calculates a standing angle according to a measured result.

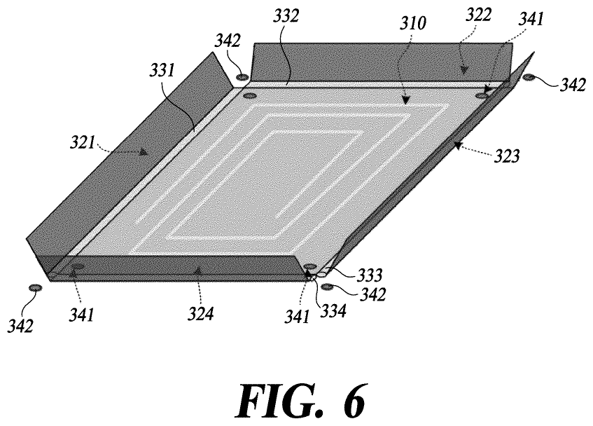

FIG. 6 is a diagram exemplarily illustrating a shape when each shielding panel is erected at a certain standing angle.

As illustrated in FIG. 6, when each of the shielding panels 321, 322, 323, and 324 is erected at a certain standing angle, the shielding panels 321, 322, 323, and 324 surround the transmitting coil 310.

As shown in FIG. 5, the shielding panels 321, 322, 323, and 324 operate in a structure that may shield all four surfaces of the transmitting coil 310 by being erected with the minimum height margin such that the shielding panels are not in contact with the bottom surface of the electric vehicle 101 according to a calculated standing angle.

As described above, the shielding panels 321, 322, 323, and 324 shield the entire transmitting coil 310, and thus, the external influence due to electromagnetic waves generated in the wireless power transmission device 300 may be minimized, and as the shielding panels 321, 322, 323, and 324 are formed, the transmission efficiency of wireless power may increase.

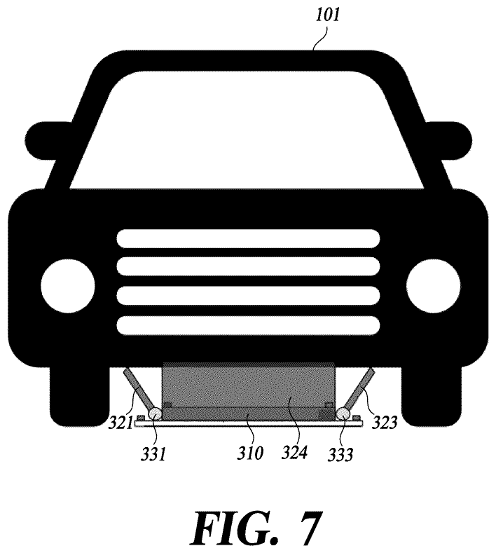

FIG. 7 is a diagram illustrating a shape of the wireless power transmission device 300 after a moving process and a standing angle calculation process of a vehicle are completed and wireless charging is started.

As shown in FIG. 7, when the wireless charging is started, the controlling unit 350 generates power of the transmitting coil 310 after the shielding panels 321, 322, 323, and 324 are erected according to the calculated standing angle, such that the influence of the electromagnetic waves generated in the wireless power transmission device 300 may be minimized.

When the wireless charging of the electric vehicle 101 is terminated, the controlling unit 350 confirms that a wireless charging signal of the transmitting coil 310 is turned off, and rotates each of the rotary shafts 331, 332, 333, and 334 to drive each of the shielding panels 321, 322, 323, and 324 to return to an initial state shown in FIG. 3.

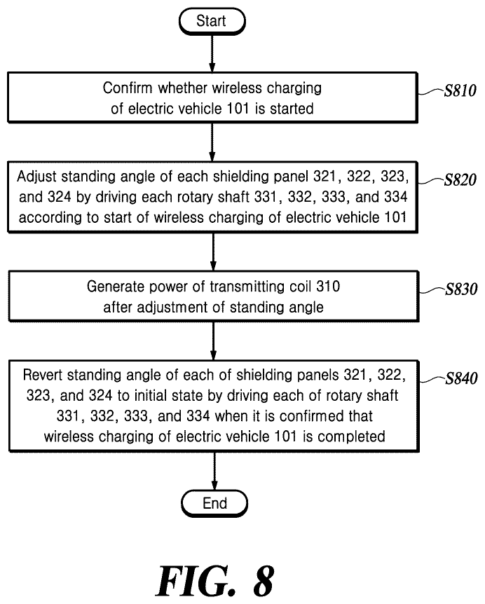

FIG. 8 is a flowchart illustrating a wireless power transmission method according to an embodiment of the present disclosure.

The wireless power transmission method according to an embodiment of the present disclosure is performed by the wireless power transmission device 300 according to an embodiment of the present disclosure.

The controlling unit 350 performs a wireless charging confirmation process of confirming whether wireless charging of the electric vehicle 101 is started (S810). Here, whether the wireless charging is started may be confirmed by confirming whether the electric vehicle 101 is stopped after approaching the wireless power transmission device 300, using sensors such as the distance sensors 341 and 342, or by receiving a signal from the electric vehicle 101 indicating the start of wireless power transmission using a separate sensor (not shown).

The controlling unit 350 drives each of the rotary shafts 331, 332, 333, and 334 according to the start of the wireless charging of the electric vehicle 101 to perform a standing angle adjustment process of adjusting a standing angle of each of the shielding panels 321, 322, 323, and 324 (S820).

The controlling unit 350 performs a power generation process of generating power of the transmitting coil 310 after the adjustment of the standing angle (S830).

When it is confirmed that the wireless charging of the electric vehicle 101 is completed, the controlling unit 350 drives each of the rotary shafts 331, 332, 333, and 334 to perform an initialization process of reducing the standing angle of each of the shielding panels 321, 322, 323, and 324 to an initial state (S840).

At least some of components described in exemplary embodiments of the present disclosure may be implemented by hardware elements including at least one of a digital signal processor (DSP), a processor, a controller, an application-specific IC (ASIC), a programmable logic device (FPGA, etc.) and other electronic devices or a combination thereof. In addition, at least some functions or processes described in exemplary embodiments may be implemented by software, and the software may be stored in a recording medium. At least some components, functions, and processes described in exemplary embodiments of the present disclosure may be implemented by a combination of hardware and software.

A method according to exemplary embodiments of the present disclosure may be written by a computer-executable program, and may also be implemented by various recording media such as a magnetic storage medium, an optical reading medium, and a digital storage medium.

Various technologies described in the present specification may be implemented by digital electronic circuitry, or computer hardware, firmware, software, or a combination thereof. The technologies may be implemented as a computer program product, that is, an information carrier, such as a machine-readable storage device (computer-readable medium) or a computer program tangibly materialized in a radio signal, for the processing by an operation of a data processing device, for example a programmable processor, a computer, or a plurality of computers, or for controlling the operation. A computer program, such as the above-described computer program(s), may be recorded in any form of a programming language including compiled or interpreted languages, and may be deployed in any form as a stand-alone program or module, component, subroutine, or other units suitable for use in a computing environment. A computer program may be deployed to be processed on one computer or a plurality of computers at one site or distributed across a plurality of sites and interconnected by a communication network.

Processors suitable for processing a computer program include, for example, both general- and special-purpose microprocessors, and any one or more processors of any kind of a digital computer. Generally, a processor may receive instructions and data from a read-only memory or random access memory or both. Elements of a computer may include at least one processor for executing instructions and one or more memory devices for storing instructions and data. Generally, a computer may include one or more mass storage devices for storing data, for example, magnetic, magneto-optical disks, or optical disks, or may be coupled to receive or transmit data therefrom or thereto, or both. Information carriers suitable for materializing computer program instructions and data include, for example, semiconductor memory devices, magnetic media such as hard disks, floppy disks, and magnetic tapes, optical media such as compact disk-read-only memory (CD-ROM) and digital video disk (DVD), magneto-optical media (ROM, read-only memory) such as floptical disk, random access memory (RAM), flash memory, erasable programmable ROM (EPROM), electrically Erasable programmable ROM (EEPROM), and the like. A processor and a memory may be supplemented by, or included in a special-purpose logic circuitry.

A processor may perform an operating system and a software application performed on the operating system. In addition, a processor device may access, store, manipulate, process, and generate data in response to execution of software. For ease of understanding, a processor device may be described as being used singly, but those skilled in the art may understand that the processor device may include a plurality of processing elements and/or a plurality of types of processing elements. For example, a processor device may include a plurality of processors or one processor and one controller. Also, other processing configurations, such as parallel processor are also possible.

Moreover, non-transitory computer-readable media may be any available media that may be accessed by a computer and include both computer storage media and transmission media.

While the present specification contains many specific implementation details, these should not be understood as limitations on the scope of any invention or of what may be claimed, but rather as descriptions of features that may be specific to certain embodiments of certain inventions. Certain features that are described in the present specification in the context of individual embodiments may also be implemented in combination in a single embodiment. Conversely, various features that are described in the context of a single embodiment may also be implemented in a plurality of embodiments separately or in any suitable subcombination. Furthermore, although features may be described as acting in a certain combination and even initially claimed as such, one or more features from a claimed combination may be excluded from the combination in some cases, and the claimed combination may be modified into a subcombination or a variation thereof.

Similarly, while operations are described in the drawings in a certain order, this should not be understood as requiring that such operations be performed in the certain order or sequential order illustrated, or that all illustrated operations be performed, to achieve desirable results. In certain cases, multitasking and parallel processing may be advantageous. In addition, the separation of various device components in the embodiments described above should not be understood as requiring such separation in all embodiments, and it should be understood that described program components and devices may generally be integrated together in a single software product or packaged into multiple software products.

Meanwhile, it should be noted that embodiments of the present disclosure disclosed in the present specification and the drawings are merely specific examples for facilitating understanding, and are not intended to limit the scope of the present disclosure. It is obvious to those skilled in the art that other variations based on the technical idea of the present disclosure may be implemented in addition to the embodiments disclosed herein.

The scope of protection of an embodiment of the present disclosure should be understood according to the following claims, and all technical ideas within the scope equivalent thereto should be understood as being included in the scope of rights of the present embodiment.

1. A wireless power transmission device for wirelessly charging an electric vehicle, comprising:
a transmitting coil configured to generate a magnetic field for wireless charging;
at least one shielding panel positioned around the transmitting coil;
at least one rotary shaft each attached to an edge of the at least one shielding panel and formed to be able to each adjust a standing angle of the at least one shielding panel by rotation; and
a controlling unit configured to drive the at least one rotary shaft to adjust the standing angle of the at least one shielding panel if wireless charging of the electric vehicle is started.

2. The wireless power transmission device of claim 1, wherein the entirety of the at least one shielding panel surrounds the transmitting coil.

3. The wireless power transmission device of claim 2, wherein the at least one shielding panel is provided in four pieces, each positioned on one of four surfaces surrounding the transmitting coil.

4. The wireless power transmission device of claim 1, wherein an upper portion of the at least one shielding panel is formed of a magnetic body, in a state where a standing angle of the at least one shielding panel is 0°.

5. The wireless power transmission device of claim 1, wherein a lower portion of the at least one shielding panel is formed of a metal material, in a state where a standing angle of the at least one shielding panel is 0°.

6. The wireless power transmission device of claim 1, further comprising:
a distance sensor for measuring a height of a bottom surface of the electric vehicle from the wireless power transmission device.

7. The wireless power transmission device of claim 6, wherein the controlling unit adjusts the standing angle by rotating the at least one rotary shaft according to the height.

8. The wireless power transmission device of claim 1, wherein the standing angle is calculated based on the height, a width of the at least one shielding panel, and a preset distance margin.

9. The wireless power transmission device of claim 6, wherein the distance sensor is provided in plurality, and at least one distance sensor is disposed inside a shape connecting the at least one rotary shaft to each other.

10. The wireless power transmission device of claim 9, wherein at least another distance sensor is disposed outside the shape connecting the at least one rotary shaft to each other.

11. A method of wireless power transmission for wirelessly charging an electric vehicle in
a wireless power transmission device, the method comprising:
a wireless charging confirmation process of confirming whether wireless charging of the electric vehicle is started;
a standing angle adjustment process of driving the at least one rotary shaft to adjust a standing angle of the at least one shielding panel according to the start of the wireless charging; and
a power generation process of generating power of the transmitting coil after adjustment of the standing angle,
wherein the wireless power transmission device includes a transmitting coil configured to generate a magnetic field for wireless charging, at least one shielding panel positioned around the transmitting coil, and at least one rotary shaft each attached to an edge of the at least one shielding panel and formed to be able to each adjust a standing angle of the at least one shielding panel by rotation.

12. The method of wireless power transmission of claim 11, wherein the entirety of the at least one shielding panel surrounds the transmitting coil.

13. The method of wireless power transmission of claim 12, wherein the at least one shielding panel is provided in four pieces, each positioned on four surfaces around the transmitting coil.

14. The method of wireless power transmission of claim 11, wherein an upper portion of the at least one shielding panel is formed of a magnetic body, in a state where a standing angle of the at least one shielding panel is 0°.

15. The method of wireless power transmission of claim 11, wherein a lower portion of the at least one shielding panel is formed of a metal material, in a state where a standing angle of the at least one shielding panel is 0°.

16. The method of wireless power transmission of claim 11, the wireless power
transmission device further comprising:
a distance sensor for measuring a height of a bottom surface of the electric vehicle from the wireless power transmission device.

17. The method of wireless power transmission of claim 16, wherein the standing angle adjustment process rotates the at least one rotary shaft according to the height to adjust the standing angle.

18. The method of wireless power transmission of claim 11, wherein the standing angle is calculated based on the height, a width of the at least one shielding panel, and a preset distance margin.

19. The method of wireless power transmission of claim 16, wherein the distance sensor is provided in plurality, and at least one distance sensor is disposed inside a shape connecting the at least one rotary shaft to each other.

20. The method of wireless power transmission of claim 19, wherein at least another distance sensor is disposed outside the shape connecting the at least one rotary shaft to each other.
